(19) United States
(12) Patent Application Publication
(10) Pub. No.: US 2024/0249039 A1
(43) Pub. Date: Jul. 25, 2024

(54) System and Method for Validating a Black-box Model

(71) Applicant: Northeastern University, Boston, MA (US)

(72) Inventors: Yun Fu, Newton, MA (US); Zaid Khan, Kenner, LA (US)

(21) Appl. No.: 18/421,910

(22) Filed: Jan. 24, 2024

Related U.S. Application Data
(60) Provisional application No. 63/481,310, filed on Jan. 24, 2023.

(51) Int. Cl. G06F 30/20

(52) U.S. Cl. CPC G06F 30/20

(57) ABSTRACT

A computer-based system and corresponding computer-implemented method for validating a black-box model are provided. An initial question is transformed into at least one additional question by rephrasing the initial question based on an initial answer from the black-box model to the initial question. A consistency metric is produced based on consistency of the initial answer and respective additional answers received from the black-box model in response to the at least one additional question. The black-box model is validated based on the consistency metric produced.

### RELATED APPLICATION

This application claims the benefit of U.S. Provisional Application No. 63/481,310, filed on Jan. 24, 2023. The entire teachings of the above application are incorporated herein by reference.

### BACKGROUND

The use of models, such as vision-language models (VLMs) and multimodal models, among other examples, has increased over time. However, current approaches for validating such models remain inadequate.

### SUMMARY

A particular area of inadequacy for model validation, including for, e.g., reliability, safety, and trustworthiness, etc., is validating black-box models, for which access to model internal details is unavailable. Embodiments disclosed herein provide a computer-based system and computer-implemented method for validating black-box models. By generating rephrasings of an initial question posed to a black-box model and analyzing the model's consistency in answering the initial question and the rephrased questions, embodiments can produce a consistency metric for the model, which, in turn, facilitates validating the model.

According to an example embodiment, a computer-implemented method for validating a black-box model comprises transforming an initial question (referred to interchangeably herein as an “original question”) into at least one additional question by rephrasing the initial question based on an initial answer from the black-box model to the initial question. The method further comprises producing a consistency metric (referred to interchangeably herein as measuring “predictive uncertainty”) based on consistency of the initial answer and respective additional answers received from the black-box model in response to the at least one additional question. The method further comprises validating the black-box model based on the consistency metric produced.

The black-box model may be at least one of a multimodal model and a vision-language model (VLM), for non-limiting examples.

The validating may include identifying a subsequent answer as correct or incorrect. The subsequent answer may be received from the black-box model in response to a subsequent question from an end user. The identifying may include determining a probability that the subsequent answer is a correct response to the subsequent question. The method may further comprise alerting the end user that the subsequent answer is correct or incorrect based on the probability determined.

The method may further comprise dynamically preempting display of a subsequent answer to an end user based on the consistency metric produced. The subsequent answer may be received from the black-box model in response to a subsequent question. The subsequent question may be received from the end user.

The method may further comprise producing a risk metric for a subsequent question to the black-box model based on the consistency metric produced. The subsequent question may be received from an end user. The risk metric may represent a probability that a subsequent answer received from the black-box model in response to the subsequent question is incorrect. The method may further comprise preempting transmission of the subsequent question to the black-box model responsive to the risk metric produced exceeding a threshold value.

The validating may include ranking the initial answer and the respective additional answers based on relative consistency of the initial answer and the respective additional answers.

The validating may include determining a deviation between respective consistencies of the respective additional answers and respective confidence scores for the respective additional answers. The respective confidence scores may be output by the black-box model. The validating may further include, responsive to the deviation determined exceeding a threshold value, alerting an end user to the deviation determined.

The rephrasing may include probabilistically sampling a distribution of potential questions to generate a given additional question of the at least one additional question. The probabilistically sampling may include determining a probability that the given additional question will cause the black-box model to produce the initial answer in response to the additional question. The probabilistically sampling may include performing nucleus sampling for non-limiting example. The probabilistically sampling may include generating the given additional question by implicitly perturbing a representation of the initial question in a feature space. The feature space may be associated with the black-box model.

At least one of the initial question, the initial answer, a given additional answer of the respective additional answers, and an additional question of the at least one additional question may include natural language data, text data, speech data, image data, video data, audio data, another type of data, or a combination thereof, for non-limiting examples.

According to another example embodiment, a computer-based system for validating a black-box model comprises a question generation model, at least one processor, and a memory with computer code instructions stored thereon. The question generation model is configured to transform an initial question into at least one additional question by rephrasing the initial question based on an initial answer received from the black-box model in response to the initial question. The at least one processor and the memory, with the computer code instructions, are configured to cause the system to implement a validation module. The validation module is configured to produce a consistency metric based on consistency of the initial answer and respective additional answers received from the black-box model in response to the at least one additional question. The validation module is further configured to validate the black-box model based on the consistency metric produced.

Alternative computer-based system embodiments parallel those described above in connection with the example computer-implemented method embodiment.

According to yet another example embodiment, a non-transitory computer-readable medium has encoded thereon a sequence of instructions which, when loaded and executed by at least one processor, causes the at least one processor to transform an initial question into at least one additional question by rephrasing the initial question based on an initial answer from the black-box model to the initial question. The sequence of instructions further causes the at least one processor to produce a consistency metric based on consistency of the initial answer and respective additional answers received from the black-box model in response to the at least one additional question. The sequence of instructions further causes the at least one processor to validate the black-box model based on the consistency metric produced.

Alternative non-transitory computer-readable medium embodiments parallel those described above in connection with the example computer-implemented method embodiment.

It is noted that example embodiments of a method, system, and computer-readable medium may be configured to implement any embodiments, or combination of embodiments, described herein.

It should be understood that example embodiments disclosed herein can be implemented in the form of a method, apparatus, system, or computer-readable medium with program codes embodied thereon.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A is a block diagram of a computer-based system that includes an example embodiment of the present invention.

FIG. 1B is a block diagram of an example embodiment of an architecture for black-box visual model validation.

FIG. 1C is a block diagram of another example embodiment of an architecture for black-box visual model validation.

FIG. 2 is a plot of selective visual question answering (VQA) performance of a vision-language model (VLM) on according to an example embodiment.

FIGS. 3A-3C are plots of distributions of confidence scores according to an example embodiment.

FIGS. 4A and 4B illustrate using model-generated rephrasings to identify errors in model predictions according to an example embodiment.

FIG. 5 is a plot of accuracy of answers of a VQA model according to an example embodiment.

FIGS. 6A-6C are plots of distributions of confidence scores according to another example embodiment.

FIG. 7 is a graph of percentages of datasets at given levels of consistency according to an example embodiment.

FIGS. 8A-8F are plots of risk-coverage curves according to an example embodiment.

FIGS. 9A and 9B are tables of coverage at a specified risk levels according to an example embodiment.

FIGS. 10A-10C are plots of risk-coverage curves according to another example embodiment.

FIGS. 11A-11D are tables of granular risk-coverage data according to an example embodiment.

FIGS. 12A and 12B illustrate mapping rephrasings into parts of an embedding space according to an example embodiment.

FIGS. 13A-13C are tables of VQA model calibration data according to an example embodiment.

FIG. 14 illustrates generating rephrasings according to an example embodiment.

FIG. 15 is a flow diagram of an example embodiment of a computer-implemented method.

FIG. 16 is a block diagram of an example embodiment of an internal structure of a computer optionally within an embodiment disclosed herein.

### DETAILED DESCRIPTION

A description of example embodiments follows.

When mistakes have serious consequences, reliable use of a model, such as a vision-language model (VLM) or a multimodal model, among other examples, may require understanding when predictions of the model are trustworthy. One existing approach is selective prediction, in which a model is allowed to abstain if it is uncertain. Existing methods for selective prediction require access to model internals, retraining, and/or a large number of model evaluations, and cannot be used for black-box models available only through an application programming interface (API). This may be a barrier to using powerful commercial foundation models in risk-sensitive applications. Furthermore, existing work has largely focused on unimodal foundation models. Certain embodiments offer improved selective prediction in a black-box VLM by measuring consistency over neighbors of a visual question. Further, some embodiments provide a probing model as a proxy for directly sampling a neighborhood of a visual question. Described herein are experiments testing embodiments on in-distribution, out-of-distribution (OOD), and adversarial questions. Embodiments can use consistency of a VLM across rephrasings of a visual question to identify and reject high-risk visual questions, even in OOD and adversarial settings, thus enabling safe use of black-box VLMs.

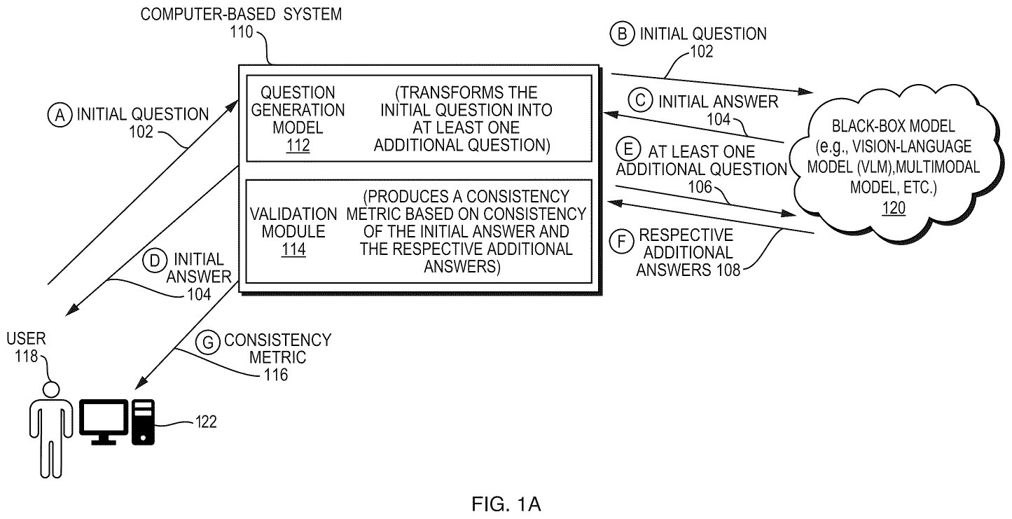

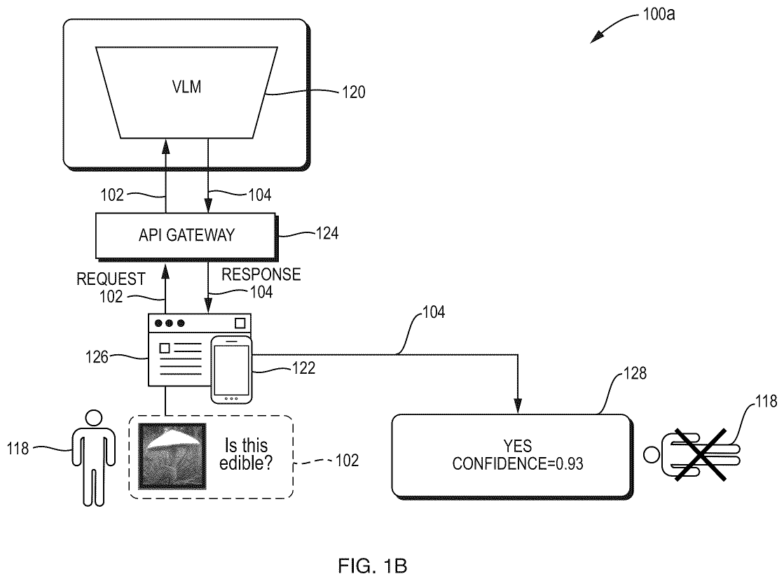

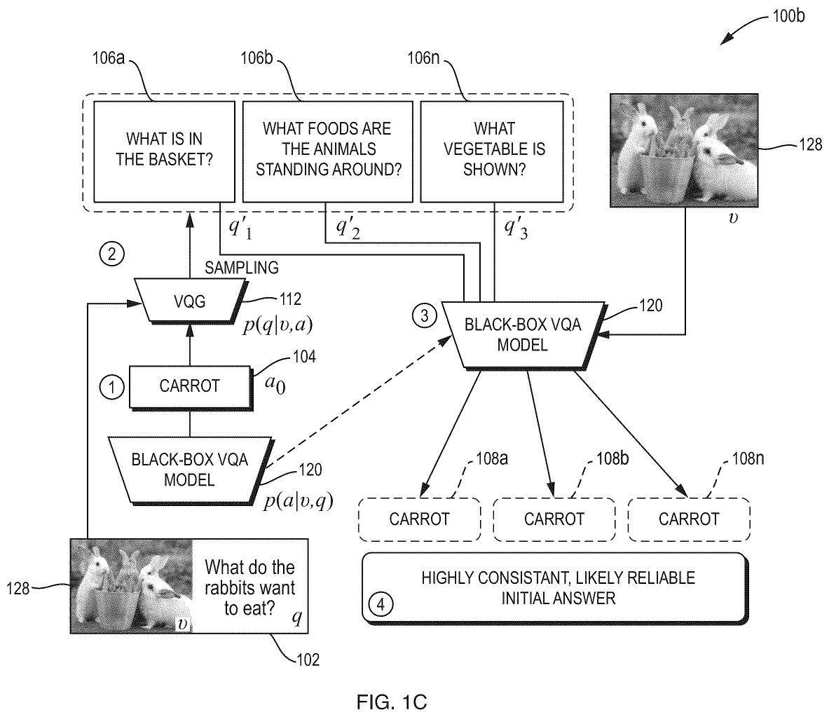

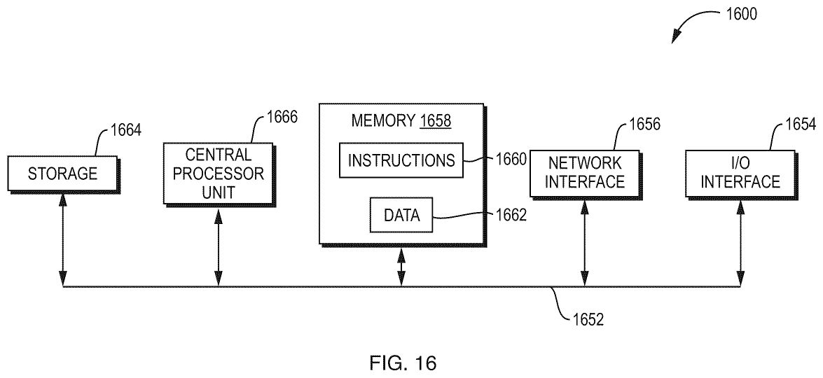

FIG. 1A is a block diagram of a computer-based system 110 that includes an example embodiment of the present invention. In the example embodiment of FIG. 1A, the system 110 comprises a question generation model 112, at least one processor (not shown), and memory (not shown) with computer code instructions (not shown) stored thereon, such as disclosed further below with respect to FIG. 16. The question generation model 112 may be configured to transform an initial question 102 into at least one additional question 106 by rephrasing the initial question 102 based on an initial answer received 104 from a black-box model 120 in response to the initial question 102. In the example embodiment of FIG. 1A, the initial question 102 is received from a user device 122 of a user 118 at step A and transmitted to the black-box model 120 at step B, while the initial answer 104 is then received from the black-box model 120 at step C and transmitted to the user device 122 at step D, followed by transmitting the at least one additional question 106 to the black-box model at step E, for non-limiting example. The user device 115 may be a personal computer (PC), laptop, table, smartphone, or any other suitable known user device, for non-limiting examples. To continue, the at least one processor and the memory, with the computer code instructions, may be configured to cause the system 110 to implement a validation module 114. The validation module 114 may be configured to produce a consistency metric 116 based on consistency of the initial answer 104 and respective additional answers 108 received from the black-box model 120 in response to the at least one additional question 106. In the example embodiment of FIG. 1A, the respective additional answers 108 may be received from the black-box model 120 at step F, while the consistency metric 116 may be transmitted to the user device 122 at step G, for non-limiting examples. To continue, the validation module 114 may be further configured to validate the black-box model 120 based on the consistency metric 116 produced.

The black-box model 120 may be at least one of a multimodal model and a VLM, for non-limiting examples. The black-box model 120 may also function as the question generation model 112.

The validation module 114 may be further configured to identify a subsequent answer (not shown) as correct or incorrect. The subsequent answer may be received from the black-box model 120 in response to a subsequent question (not shown) from an end user, e.g., the user 118. To identify the subsequent answer as correct or incorrect, the validation module 114 may be further configured to determine a probability (not shown) that the subsequent answer is a correct response to the subsequent question. The validation module 114 may be further configured to alert the end user that the subsequent answer is correct or incorrect based on the probability determined.

The validation module 114 may be further configured to dynamically preempt display, e.g., on the user device 112, of a subsequent answer (not shown) to an end user, e.g., the user 118, based on the consistency metric 116 produced. The subsequent answer may be received from the black-box model 120 in response to a subsequent question (not shown). The subsequent question may be received from the end user, e.g., the user 118.

The validation module 114 may be further configured to produce a risk metric (not shown) for a subsequent question (not shown) to the black-box model 120 based on the consistency metric 116 produced. The subsequent question may be received from an end user, e.g., the user 118. The risk metric may represent a probability (not shown) that a subsequent answer (not shown) received from the black-box model 120 in response to the subsequent question is incorrect. The validation module 114 may be further configured to preempt transmission of the subsequent question to the black-box model 120 responsive to the risk metric produced exceeding a threshold value (not shown).

The validation module 114 may be further configured to rank the initial answer 104 and the respective additional answers 108 based on relative consistency (not shown) of the initial answer 104 and the respective additional answers 108.

The validation module 114 may be further configured to determine a deviation between respective consistencies (not shown) of the respective additional answers 108 and respective confidence scores (not shown) for the respective additional answers 108. The respective confidence scores may be output by the black-box model 120. The validation module 114 may be further configured to, responsive to the deviation determined exceeding a threshold value (not shown), alert an end user, e.g., the user 118, to the deviation determined.

The question generation model 112 may be further configured to probabilistically sample a distribution of potential questions (not shown) to generate a given additional question (not shown) of the at least one additional question 106. The question generation model 112 may be further configured to probabilistically sample the distribution of potential questions using nucleus sampling, for non-limiting example. The question generation model 112 may be further configured to determine a probability that the given additional question will cause the black-box model 120 to produce the initial answer 104 in response to the given additional question. The question generation model 112 may be further configured to generate the given additional question by implicitly perturbing a representation (not shown) of the initial question 104 in a feature space (not shown). The feature space may be associated with the black-box model 120.

At least one of the initial question 102, the initial answer 104, a given additional answer of the respective additional answers 108, and a given additional question of the at least one additional question 106 may include natural language data, text data, speech data, image data, video data, audio data, another type of data, or a combination thereof, for non-limiting examples.

FIG. 1B is a block diagram of an example embodiment of an architecture 100a for black-box model validation. In the example embodiment of FIG. 1B, the architecture 100a includes a black-box model 120, an API gateway 124, and a user-facing application 126. The black-box model 120 may be, e.g., a VLM, such as a large, pretrained VLM, for non-limiting example. In addition, the black-box model 120 may be a powerful model that is accessible only through an API, e.g., the API gateway 124; similarly, the black-box model 120 may be provided on a third-party “model-as-a-service” (MaaS) basis, for non-limiting example. The user-facing application 126 may execute on a user device 122. In the example embodiment of FIG. 1B, an end user 118 inputs a request 102 (e.g., a query or question, such as a visual question, for non-limiting example) to the application 126. As shown in FIG. 1B, for instance, the request 102 may be a question asking if a mushroom pictured in an image is edible, for non-limiting example. In turn, the application 126 transmits the request 102 via the API 124 to the black-box model 120. The black-box model 120 then outputs a response 104 (e.g., a prediction or answer), which is received by the application 126 via the API 124. In addition, the response 104 may have an associated confidence score 128. As shown in FIG. 1B, for instance, the response 104 may be a “yes” prediction or answer and the confidence score 128 may indicate that the response 104 has an associated confidence value of 0.93 (i.e., 93% confidence), for non-limiting example. However, it may be uncertain whether the response 104 of the black-box model 120 is a reliable prediction for the visual question 102. For instance, it may not be possible to access or determine internals of the black-box model 120 such as its features, gradients, weights, and/or retraining, among other examples. Given a lack of visibility into the black-box model 120's internal workings, it may be unclear how to use the black-box model 120 safely. Thus, as shown in FIG. 1B, despite the high confidence score 128, the black-box model 120's response 104 affirming the mushroom's edibility may ultimately be incorrect, and if the end user 118 mistakenly trusts the response 104, this may result in the end user 118's untimely demise.

FIG. 1C is a block diagram of another example embodiment of an architecture 100b for black-box model validation. In the example embodiment of FIG. 1C, the architecture 100b includes a computer-based system (not shown), a validation module (not shown), a question generation model 112 (e.g., a visual question generation (VQG) model, for non-limiting example), and a black-box model 120 (e.g., a black-box visual question answering (VQA) model, for non-limiting example). The question generation model 112 may be configured to transform an initial question 102 into additional questions 106a-n by rephrasing the initial question 102 based on an initial answer received 104 from the black-box model 120 in response to the initial question 102. In the example embodiment of FIG. 1C, the initial question 102 and additional questions 106a-n are visual questions that relate to an image 128, for non-limiting example. To continue, the validation module may be configured to produce a consistency metric (not shown) based on consistency of the initial answer 104 and respective additional answers 108a-n received from the black-box model 120 in response to the additional questions 106a-n. The validation module may be further configured to validate the black-box model 120 based on the consistency metric produced. For instance, as shown in FIG. 1C, at step 4, the validation module may determine that initial answer 104 is highly consistent and likely reliable, for non-limiting example.

### 1. Introduction

Powerful models may sometimes only be available as black boxes accessible through an API [3, 32] because of commercial reasons, risk of misuse, and/or privacy considerations. A black-box model may be difficult to use safely for high-risk scenarios, in which it is preferable that a model defers to an expert or abstains from answering rather than deliver an incorrect answer [8]. Many approaches for selective prediction [8, 37] or improving the predictive uncertainty of a model exist, such as ensembling [17], gradient-guided sampling in feature space [12], retraining the model [34], or training an auxiliary module using model predictions [26]. Selective prediction has typically been studied in unimodal settings and/or for tasks with a closed-world assumption, such as image classification, and has only recently been studied for multimodal, open-ended tasks such as VQA [36]. Despite progress in selective prediction, current methods are not appropriate for models available only in a black-box setting, such as MaaS, where access to model internal representations is not available, retraining is infeasible, and/or each evaluation is expensive.

Black-box predictive uncertainty has been studied previously, but existing methods require a large number of evaluations to build an auxiliary model [3, 26], which can be prohibitively expensive when each evaluation has a non-negligible financial cost, or are designed for tasks with a closed-world assumption [2] with a small label space. Furthermore, while predictive uncertainty for unimodal large language models (LLMs) has been a subject of significant study [13-15], predictive uncertainty of VLMs has been studied only by Whitehead et al. [36], but their evaluation focuses on a white-box setting and smaller (e.g., <1b parameters) VLMs without web-scale pretraining. Black-box tuning of large models for increased performance [32] is possible, but little is known about improving or understanding predictive uncertainty for large black-box models. Disclosed herein are novel techniques for selective prediction for large, black-box VLMs, where a “black-box” designation implies that training data is private, model features and gradients are unavailable, and ensembling/retraining are not possible, all of which are typical features of MaaS.

Embodiments can apply a principle of consistency over neighborhood samplings [12] used in white-box settings for black-box uncertainty estimates of VQA models, by using question generation to approximate sampling from a neighborhood of an input question without access to features of the input question. First, selective prediction on VQA across in-distribution, OOD, and adversarial inputs using a large VLM is described. Also described is how rephrasings of a question can be viewed as samples from a neighborhood of a visual question pair. Embodiments can use a VQG model as a probing model to produce rephrasings of questions given an initial answer from a black-box VLM, thereby allowing embodiments to approximately sample from a neighborhood of a visual question pair. To quantify uncertainty in an answer to a visual question pair, embodiments may feed rephrasings of the question to a black-box VLM, and count a number of rephrasings for which an answer from the VLM remains the same. This is analogous to consistency over samples taken from a neighborhood of an input sample in feature space, but embodiments may not require access to features of a VLM. Furthermore, embodiments may not require a held-out validation set, access to original training data, or retraining a VLM, making it appropriate for black-box uncertainty estimates of a VLM. Embodiments may offer effectiveness of consistency over rephrasings for assessing predictive uncertainty using a task of selective VQA in a number of settings, including adversarial visual questions, distribution shift, and OOD detection. This document's contributions include, but are not limited to:
a) Addressing a problem of black-box selective prediction for a large VLM, using a setting of selective VQA.
b) Identifying, on in-distribution data, when a state-of-the-art large VLM does not know an answer to a question.
c) Identifying high-risk inputs for VQA based on consistency over samples in a neighborhood of a visual question.
d) Techniques that are validated on in-distribution, OOD, and adversarial visual questions, as well as techniques that are effective in a likely setting where a black-box model being probed is substantially larger than a probing model.

By identifying and applying a principle that consistency over rephrasings of a question is correlated with model accuracy on a question, embodiments can (i) select slices of a test dataset on which a model can achieve lower risk, (ii) reject OOD samples, and (iii) effectively separate right from wrong answers, even on adversarial and OOD inputs. Surprisingly, and as an example of unexpected results, embodiments are effective even though many rephrasings are not literally valid rephrasings of a question. Embodiments also facilitate reliable usage of VLMs as an API.

Furthermore, embodiments may be used to identify approximately defined concept areas where a model, e.g., a LLM, lacks an adequate understanding of a given concept. In other words, if a model outputs predictions for a concept area that has been identified by embodiments as problematic, the model's predictions in that concept area may not be considered trustworthy. Embodiments also support user-generated rephrasings of input questions for a model. In addition, embodiments can be used with, e.g., IVR (interactive voice response), FAQ (frequently asked questions), chatbot, and CAPTCHA (Completely Automated Public Turing test to tell Computers and Humans Apart) systems, among other examples.

Embodiments provide technical improvements for models because a consistency metric according to principles of the present disclosure allows models to reject problematic questions more accurately and efficiently than conventional approaches, such as using confidence scores.

### 2. Motivating Experiment

Predictive uncertainty of a large VLM may be determined through a lens of selective VQA. In contrast to a classical VQA setting, where a model is forced to answer, in selective VQA, a model may be allowed to abstain from answering. For safety and reliability, it may be important to examine both OOD and adversarial inputs, on which it may be expected that a VLM will have a high error rate if forced to answer every OOD or adversarial question posed to the model. However, because a VLM may be allowed to abstain, in principle, the model can achieve low risk (e.g., low error rate) on a slice of a dataset corresponding to questions that it knows the answer to. In a black box setting, only raw confidence scores for answer candidates may be likely to be available, so confidence of the most likely answer may be used as uncertainty.

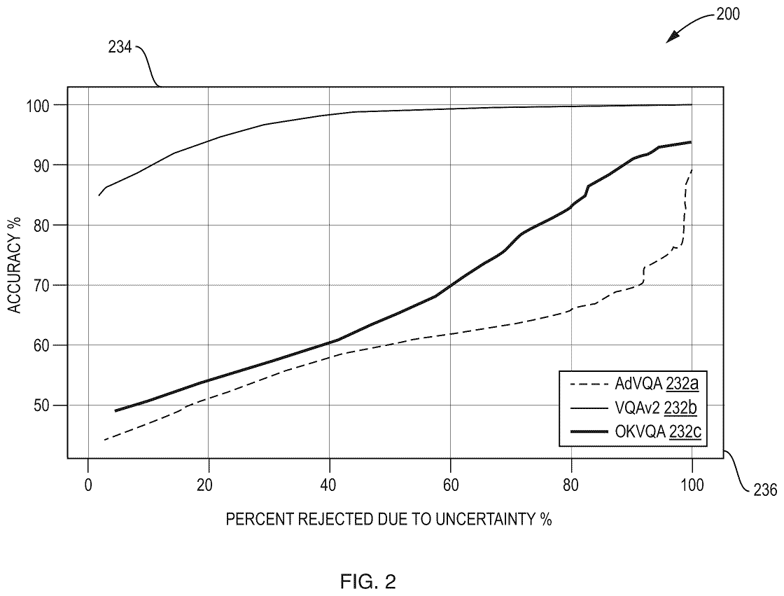

FIG. 2 is a plot 200 of selective VQA performance of a VLM on three datasets 232a-c according to an example embodiment. The VLM may be a BLIP (Bootstrapping Language-Image Pre-training) [19] model finetuned on a VQAv2 training set [10] using confidence scores on validation sets of adversarial (AdVQA, Sheng et al. [31]), OOD (OK-VQA (Outside Knowledge VQA), Marino et al. [25]), and in-distribution (VQAv2) datasets. As shown in FIG. 2, percentage accuracy 234 for each of the datasets 232a-c is plotted as a function of percentage of questions rejected due to uncertainty 236 from each of the respective datasets 232a-c. For the in-distribution dataset (VQAv2), the model may be quickly able to identify which questions it is likely to know an answer to, achieving nearly perfect accuracy by rejecting the most uncertain 40% of the dataset. However, for the OOD and adversarial datasets, the model may have more difficulty identifying which questions it should abstain from—after rejecting 50% of questions, the model may still have an error rate of ˜ 40%.

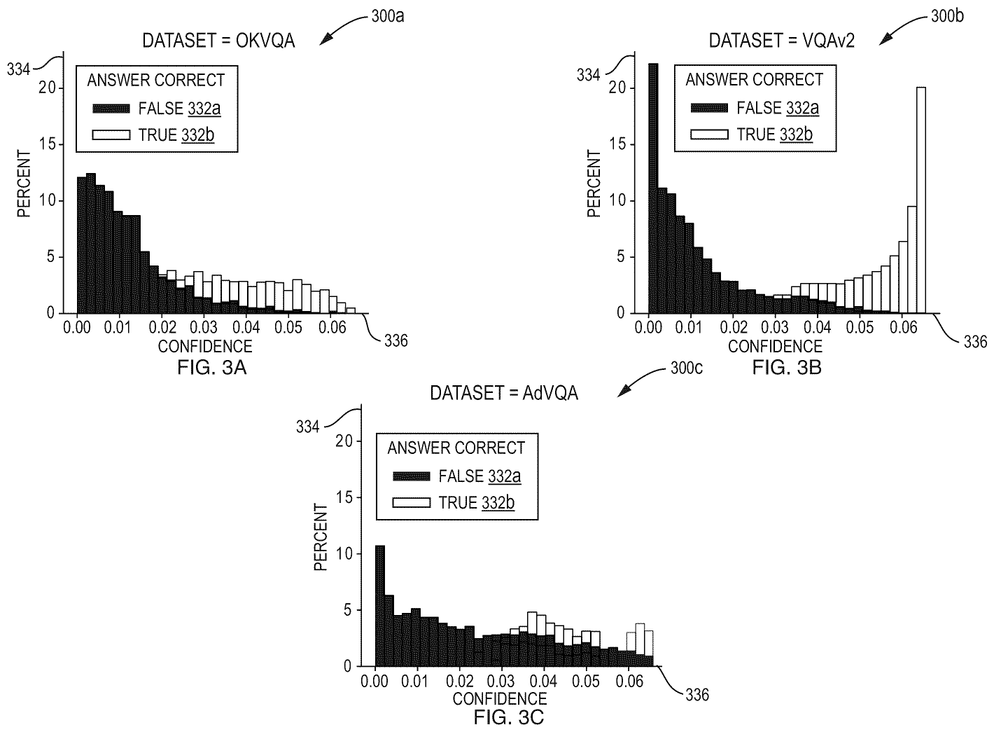

The reason for this may be evident in FIGS. 3A-3C, which are plots 300a-c of distributions of confidence scores according to an example embodiment. FIG. 3A is a plot 300a of a distribution (i.e., as a percentage 334 of a dataset) of confidence 336 scores for incorrect 332a and correct 332b answers for OOD visual questions using dataset OK-VQA. FIG. 3B is a plot 300b of a distribution (i.e., as a percentage 334 of a dataset) of confidence 336 scores for incorrect 332a and correct 332b answers for in-distribution visual questions using dataset VQAv2. FIG. 3C is a plot 300c of a distribution (i.e., as a percentage 334 of a dataset) of confidence 336 scores for incorrect 332a and correct 332b answers for adversarial visual questions using dataset AdVQA. As shown in FIG. 3B, for in-distribution visual questions, the confidence distribution 300b may be bimodal, and the incorrect 332a and correct 332b answers may be clearly separated by confidence 336. However, for OOD (OK-VQA) and adversarial visual (AdVQA) questions, confidence 336 scores alone may not work well to separate right from wrong answers. Thus, as shown in FIG. 3A, for OOD visual questions, many correctly 332b answered questions may be low confidence 336 and difficult to distinguish from incorrectly 332a answered questions. A similar situation may occur for adversarial visual questions, as shown in FIG. 3C, in which many questions may be incorrectly 332a answered with high confidence 336.

In an example embodiment, the displayed confidence 336 scores in FIGS. 3A-3C may be raw confidence scores. Details of calibrating confidence scores are provided hereinbelow.

Although a strategy of using model confidence alone to detect questions the model cannot answer may be effective for in-distribution visual questions, this strategy may fail on OOD and adversarial visual questions. Embodiments identify and apply the foregoing insight.

### 3. Exemplary Method

### 3.1 Task Definition and Background

Given an image v and question q, a task of selective VQA may be to decide whether a model f_{VQA} (v, q) should predict an answer a, or abstain from making a prediction. A typical solution to this problem may be to train a selection function g(⋅) that produces an abstention score pᵣₑⱼ∈[0, 1]. The simplest selection function may be to take a rejection probability pᵣₑⱼ=1−p(a|q, v) where p(a|q, v) is the model confidence that a is the answer, and then use a threshold τ so that the model abstains when pᵣₑⱼ>τ and predicts otherwise. A more complex approach taken by Whitehead et al. is to train a parametric selection function g(zᵥ, z_{q}; θ) where zᵥ and z_{q} are a model's dense representations of a question and image respectively. The parameters θ may be optimized on a held-out validation set, effectively training a classifier to predict when f_{VQA} will predict incorrectly on an input visual question v, q.

In a black box setting, access to dense representations zᵥ, z_{q} of an image v and question q may typically be forbidden. Furthermore, even if access to the representations is allowed, a large number of evaluations of f_{VQA} may be needed to obtain training data for a selection function. Existing methods for selective prediction typically assume and evaluate a fixed set of classes, but for VQA, a label space can shift for each task (differing sets of acceptable answers for different types of questions) or be open-set.
a) Embodiments may function effectively without requiring access to a black-box model's internal representations of v, q.
b) Embodiments may be model agnostic, given that an architecture of a black-box model may be unknown.
c) Embodiments may function effectively without requiring a large number of predictions from a black-box model to train a selection function, because each usage of the black-box model may incur a financial cost, which can be substantial if a large number of predictions is needed to train an auxiliary model.
d) Similarly, embodiments may function effectively without requiring a held-out validation set for calibrating predictions, because this may potentially require a large number of evaluations of a black-box model.

### 3.2 Deep Structure and Surface Forms

Within the field of linguistics, a popular view first espoused by Chomsky [5] is that every natural language sentence has both a surface form and a deep structure. Multiple surface forms can be instances of the same deep structure. Simply put, multiple sentences that have different words arranged in different orders can mean the same thing. A rephrasing of a question may correspond to an alternate surface form, but the same deep structure. It thus may be expected that an answer to a rephrasing of a question may be the same as the original question. If an answer to a rephrasing is inconsistent with an answer to an original question, it may indicate that a model is sensitive to variations in a surface form of the original question. This may further indicate that the model's understanding of a question is highly dependent on superficial characteristics, making it a good candidate for abstention. Embodiments may leverage the principle that inconsistency on rephrasings can be used to better quantify predictive uncertainty and reject questions a model has not understood.

### 3.3 Rephrasing Generation as Neighborhood Sampling

The idea behind many methods for representation learning is that a good representation should map multiple surface forms close together in feature space. For example, in contrastive learning, variations in surface form may be generated by applying augmentations to an input, and a distance between multiple surface forms may be minimized. In general, a characteristic of deep representation is that surface forms of an input may be mapped close together in feature space. Previous work, such as Attribution-Based Confidence [12] and Implicit Semantic Data Augmentation [35], exploit this by perturbing input samples in feature space to explore a neighborhood of an input. In a black box setting, access to features of a model may be unavailable, so a direct way to explore a neighborhood of an input in feature space may not exist. An alternate surface form of an input may be mapped close to an original input in feature space. Thus, a surface form variation of an input may be a neighbor of the input in feature space. Generating a surface form variation of a natural language sentence may correspond to a rephrasing of the natural language sentence. Because a rephrasing of a question may be a surface form variation of the question, and surface form variations of an input may be mapped close to the original input in feature space, a rephrasing of a question may be analogous to a sample from a neighborhood of the question. Embodiments employ the foregoing principle.

### 3.4. Cyclic Generation of Rephrasings

One way to generate a rephrasing of a question may be to invert a VQA problem, as is done in VQG. Let p(V), p(Q), p(A) be distributions of images, questions, and answers, respectively. VQG may be framed as approximating p(Q|A, V), in contrast to VQA, which approximates p(A|Q, V). Embodiments may probe predictive uncertainty of a black-box VQA model f_{BB}(⋅) on an input visual question pair v, q where v˜p (V) is an image and q˜p(Q) is a question. The VQA model f_{BB} may approximate p(A|Q, V). Let an answer a assigned the highest probability by the VQA model f_{BB}(⋅) be taken as a prospective answer. A VQG model f_{VQG}≈p(Q|A, V) may then be used to generate a rephrasing of an input question q. To see how, consider feeding the highest probability answer a from f_{BB}(⋅)˜ p(A|Q, V) into f_{VQG}≈p(Q|A, V) and then sampling a sentence q′ ˜ f_{VQG}≈p(Q|A, V) from the VQG model. In the case of an ideal f_{VQG}(⋅) and perfectly consistent f_{BB}(⋅), q′ may be a generated question for which p(a|q′, v)≥ p(aᵢ|q′, v) ∀aᵢ∈A, with equality occurring in the case that aᵢ=a. So, q′ may be a question having the same answer as q, which may, practically speaking, be a rephrasing. Below is a listing of an exemplary Method 1 for probing predictive uncertainty of a black-box VLM:

Method 1: Probing Predictive Uncertainty of a Black-Box VLM

```
Input: v, q, k
Data: f_{BB}, f_{VQG}
Result: c ∈ [symbol]   : consistency of f_{BB} over k
  rephrasings of v, q
a₀ ← f_{BB} (q, v);
c ← 0;
for i ← 0 to k do
  q′ ← nucleus_sample (f_{VQG}(v, a₀));
  a′ ← f_{BB} (q′, v );
  if a′ = a₀ then
    c ← c + 1;
  end
end
return c ÷ k
```

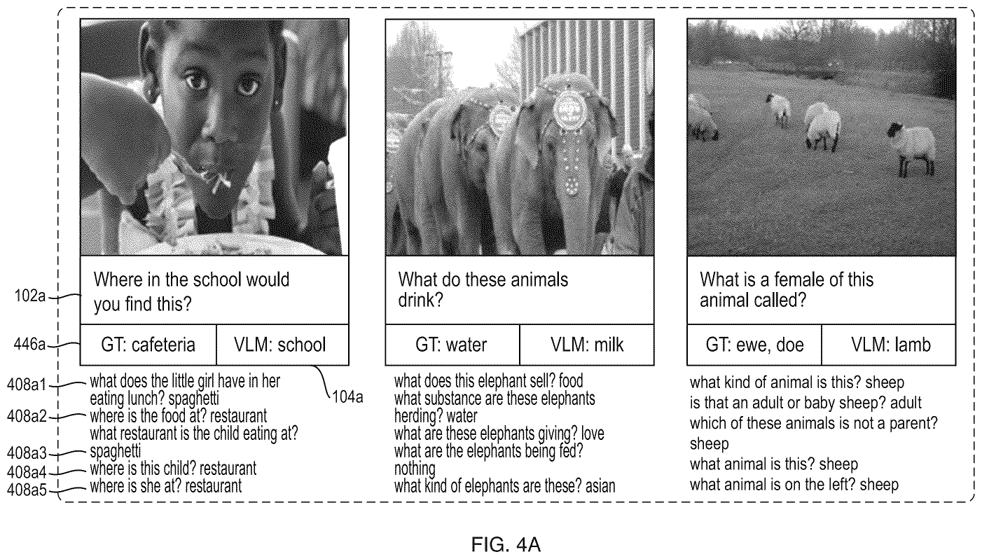

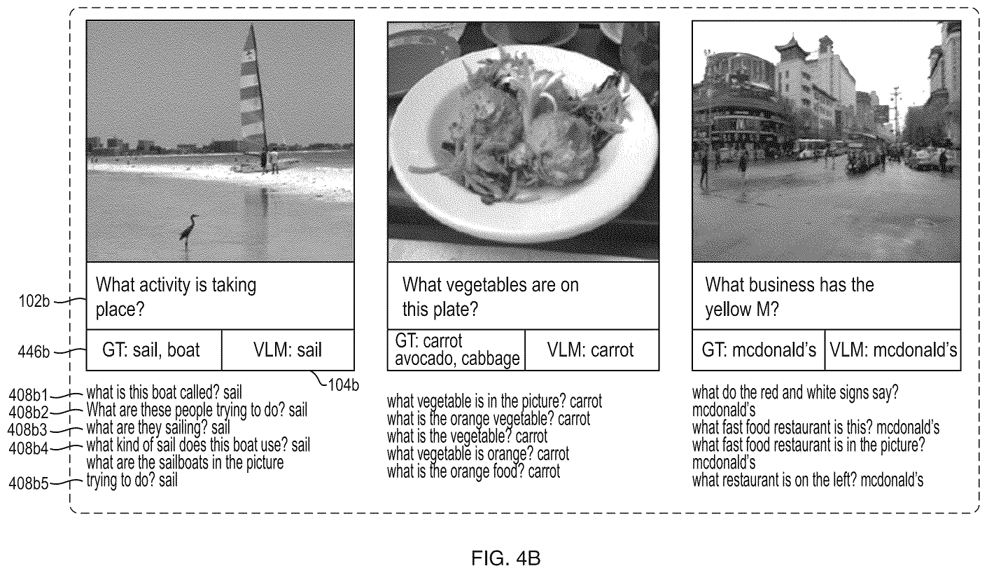

To continue, embodiments may ask a black-box model for an answer to a visual question, then give the predicted answer to a VQG model to produce a question q′ conditioned on an image v and an answer a by the black-box model, which may correspond to a question determined by the VQG model as likely to lead to the predicted answer a. Embodiments may apply a principle that, if rephrasings generated by f_{VQG} are of sufficient quality, then f_{BB} may be consistent on the rephrasings, and any observed inconsistency may indicate a problem with f_{BB}. In practice, each q′ may not guaranteed to be a rephrasing (see FIGS. 4A and 4B, described in more detail hereinbelow) due to, for instance, a probabilistic nature of a sampling process. The VQG model can be trained by following any procedure that results in a model approximating p(a|q, v) that is an autoregressive model capable of text generation conditional on multimodal image-text input. An exemplary training procedure of a VQG model is discussed in detail hereinbelow.

FIGS. 4A and 4B illustrate using model-generated rephrasings to identify errors in model predictions with BLIP as the black-box f_{BB} according to an example embodiment.

FIG. 4A illustrates high-confidence (e.g., 90^{th} percentile) answers that are actually wrong, as identified by their low consistency across rephrasings. For instance, as shown in FIG. 4A, initial question 102a associated with image 128a may have a ground truth (GT) answer 446a of “cafeteria”, but a VLM may instead output an incorrect initial answer 104a of “school” with high confidence. In response to rephrasings of the initial question 102a, the VLM may output additional answers 408a1-5 with high confidence that are not only incorrect (i.e., “spaghetti” in 408a1 and 408a3 and “restaurant” in 408a2 and 408a4-5) with respect to GT answer 446a, but also inconsistent (i.e., as between (i) 408a1 and 408a3 and (i) 408a2 and 408a4-5).

FIG. 4B illustrates low-confidence (e.g., 10^{th} percentile) answers that are actually correct, as identified by their high consistency across rephrasings. For instance, as shown in FIG. 4B, initial question 102b associated with image 128b may have a GT answer 446b of “sail” or “boat”; another VLM may further output a correct initial answer 104b of “sail” despite having low confidence. In response to rephrasings of the initial question 102b, the other VLM may output additional answers 408b1-5 that are both correct with respect to GT answer 446b and fully consistent, again, despite their low confidence scores.

### 3.5. Exemplary VOG Model Implementation

Embodiments may initialize a VQG model f_{VQG} from, e.g., a BLIP checkpoint pretrained on 129 m image-text pairs, and train it to maximize p(a|q, v) using a standard language modeling loss. Some embodiments may use exemplary Equation 1 below:

$${ℒ}_{VQG} = - {\sum }_{n = i}^{N} log {P}_{θ} ( {y}_{n} \vert {y}_{< n} , a , v ) \qquad ( 1 )$$

In the above exemplary Equation 1, y₁, y₂, . . . yₙ may be tokens of a question q and a, v may be a GT answer and image, respectively, from a VQA triplet (v, q, a). Embodiments may train for, e.g., ten epochs, using an AdamW (Adam weight decay) [23] optimizer with a weight decay of 0.05, and decay the learning rate linearly to 0 from 2e-5. Embodiments may use a batch size of, e.g., 64 with an image size of, e.g., 480×480, and may train the model on the VQAv2 training set [10]. To sample questions from the VQG model, embodiments may use, e.g., nucleus sampling with a top-p of 0.9.

### 4. Quantitative/Qualitative Examples and Results

Predictive uncertainty may be probed in a black-box VQA setting over two large VLMs and three datasets. The primary task used to probe predictive uncertainty may be selective VQA, for which a detailed description is given hereinabove. Further examples and results are described hereinbelow.

### 4.1. Exemplary Methodology

Black-box Models: An exemplary methodology may include a black-box VQA model f_{BB} and a rephrasing generator f_{VQG}. An exemplary training procedure for a rephrasing generator f_{VQG} is described hereinabove. ALBEF (ALign the image and text representations BEfore Fusing) [18], BLIP [19], and BLIP-2[20] may be used as black-box models, for non-limiting examples. ALBEF and BLIP may have, e.g., ≈200 m parameters, while a version of BLIP-2 used in the exemplary methodology may be based on, e.g., a 11b parameter FLAN-T5 (Fine-tuned LAnguage Net Text-To-Text Transfer Transformer) [6] model. ALBEF may be pretrained on, e.g., 14 m image-text pairs, while BLIP may be pretrained on, e.g., over 100 m image-text pairs, and BLIP-2 may be aligned on, e.g., 4 m images. Official checkpoints provided by the authors may be used, finetuned on, e.g., Visual Genome [16] and VQAv2 [10], with, e.g., 1.4 m and 440 k training triplets respectively.

Datasets: Evaluations may be performed in three settings: in-distribution, OOD, and adversarial. For the in-distribution setting, pairs from the VQAv2 validation set may be used following selection of [30]. For the OOD setting, OK-VQA [25], a dataset for question answering on natural images that may require outside knowledge, may be used. OK-VQA may be a natural choice for an OOD selective prediction task, because many questions may require external knowledge that a VLM may not have acquired, even through large scale pretraining. On such questions, a model that knows what it doesn't know may abstain due to lack of requisite knowledge. Finally, AdVQA may be used for adversarial visual questions. Official validation splits provided by the authors may be used. The OK-VQA, AdVQA, and VQAv2 validation sets may contain, e.g., 5 k, 10 k, and 40 k questions, respectively.

### 4.2 Properties of Consistency

Properties of consistency may be analyzed to determine the below items, for non-limiting examples:
a) A correlation between increased consistency on rephrasings and model accuracy on an original question.
b) Confidence distributions for different consistency levels.
c) Consistency distributions across different datasets.

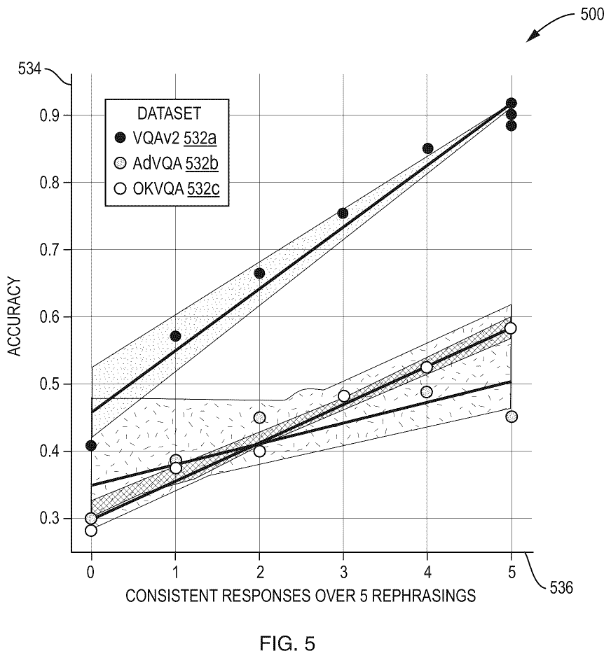

FIG. 5 is a plot 500 of accuracy 534 of answers when f_{BB} is BLIP by how consistent 536 each answer was over up to five rephrasings of an original question. As shown in FIG. 5, consistency over rephrasings may be correlated with accuracy across all three datasets 532a-c, though the correlation may be weakest on adversarial data. Increased consistency on the rephrasings of a question may imply lower risk on an original answer to the original question.

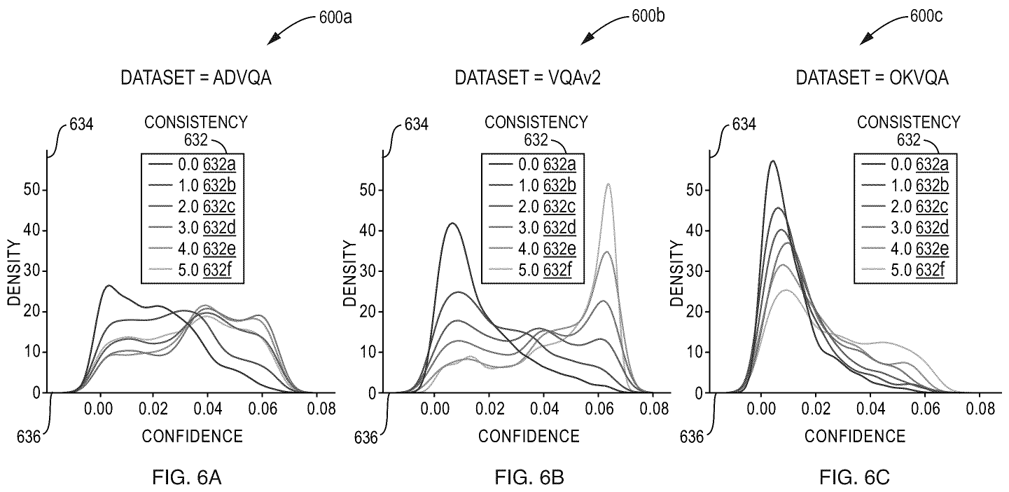

Next, FIGS. 6A-6C illustrate how a distribution of model confidence varies across consistency levels. FIG. 6A is a plot 600a of a distribution 634 of confidence 636 scores for dataset AdVQA when f_{BB} is BLIP at each consistency level 632a-f. FIG. 6B is a plot 600b of a distribution 634 of confidence 636 scores for dataset VQAv2 when f_{BB} is BLIP at each consistency level 632a-f. FIG. 6C is a plot 600c of a distribution 634 of confidence 636 scores for dataset OK-VQA when f_{BB} is BLIP at each consistency level 632a-f. As shown in FIGS. 6A-6C, across all datasets, slices of a dataset at higher consistency 632 levels, e.g., 632f, may also have a greater proportion of high-confidence 636 answers, but may retain a substantial proportion of low confidence 636 answers. This may show that consistency 632 and confidence 636 are not equivalent, and define different orderings on a set of questions and answers. Put another way, low confidence 636 on a question may not preclude high consistency 632 on a question, and similarly, high confidence 636 on a question may not guarantee that the model will be highly consistent 632 on rephrasings of a question.

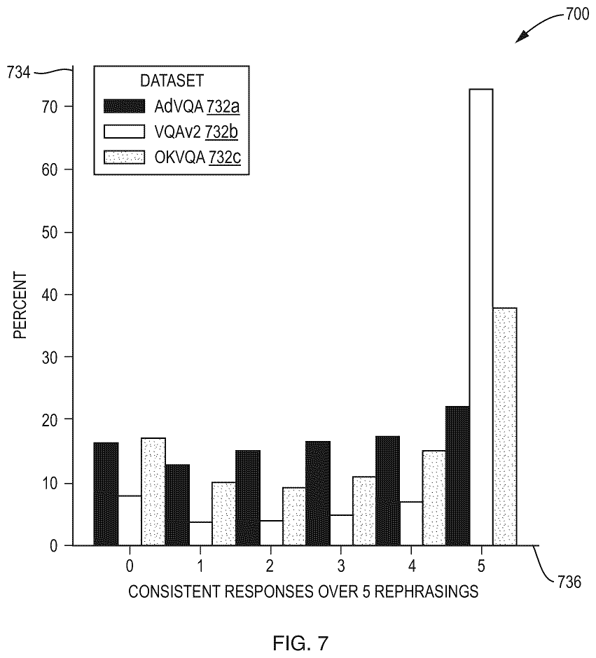

Finally, FIG. 7 is a plot 700 of percentage 734 of each dataset 732a-c at a given consistency 736 level. As shown in FIG. 7, in-distribution dataset 732b, VQAv2, may have a highest proportion of questions, with five agreeing neighbors, with all other consistency 736 levels making up the rest of the dataset 732b. For the OOD dataset 732c (OK-VQA), a substantial proportion of questions (≈40%) may have five agreeing neighbors, with the rest of the dataset 732c shared roughly equally between the other consistency 736 levels. On the adversarial dataset 732a (AdVQA), the distribution may be nearly flat, with equal slices of the dataset 732a at each consistency level. One conclusion from this is that higher consistency 736 may not necessarily be rarer, and may be highly dependent on how well a model understands a data distribution a question is drawn from.

### 4.3. Selective VOA with Neighborhood Consistency

Consistency over rephrasings may be analyzed in the setting of selective VQA with respect to the following uses of consistency over rephrasings, for non-limiting examples:
a) Selecting slices of a test dataset which a model understands well (achieves lower risk), or alternatively, identifying questions the model doesn't understand, and should reject (high risk).
b) Identifying low/high risk questions in OOD and adversarial settings.
c) Situations where a question generator is much smaller than a black-box model.

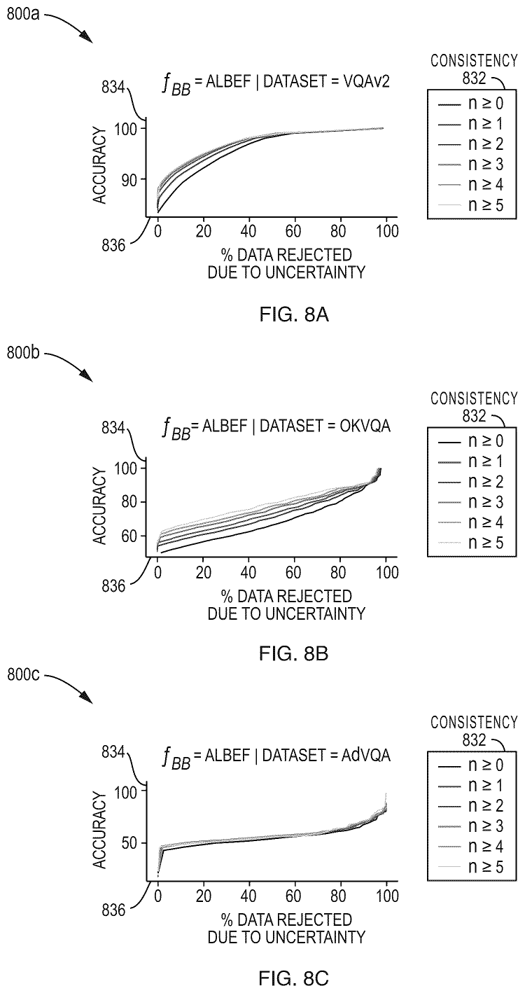

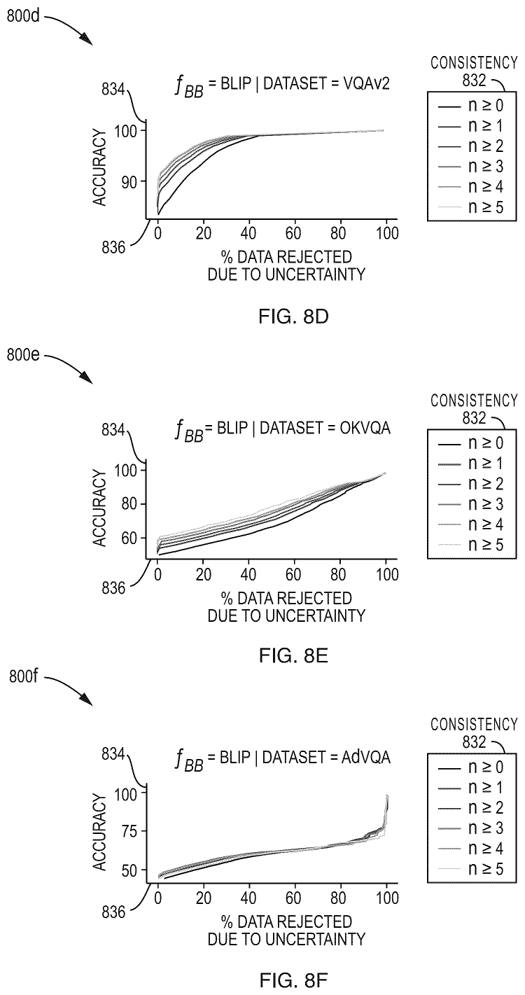

A task of selective VQA may be used to analyze leveraging consistency for separating low-risk from high-risk inputs. FIGS. 8A-8C are plots 800a, 800b, and 800c of risk-coverage curves for in-distribution (VQAv2 dataset), OOD (OK-VQA dataset), and adversarial visual (AdVQA dataset) questions, respectively, with ALBEF as a black-box f_{BB}. FIGS. 8D-8F are plots 800d, 800e, and 800f of risk-coverage curves for in-distribution (VQAv2 dataset), OOD (OK-VQA dataset), and adversarial visual (AdVQA dataset) questions, respectively, with BLIP as a black-box f_{BB}. Each plot 800a-800f shows a risk-coverage curve or tradeoff for questions from slices of the test datasets at different consistency 832 levels and plots percentage accuracy 834 as a function of percentage of questions rejected due to uncertainty 836. A curve labeled n≥k shows a risk-coverage tradeoff for a slice of a target dataset where answers of a model are consistent 832 over at least k rephrasings of an original question. For example, a curve labeled as n≥3 shows a risk-coverage tradeoff for questions on which three or more neighbors (rephrasings) were consistent 832 with an original answer. Hence, a n≥0 curve is a baseline representing a risk-coverage curve for any question, regardless of consistency 832. If greater consistency 832 over rephrasings is indicative over lower risk (and a higher probability the model knows the answer), it may be expected that a model can achieve lower risk on slices of a dataset that the model is more consistent on. On in-distribution visual questions (VQAv2), as shown in FIGS. 8A and 8D, a model may achieve lower risk at equivalent coverage for slices of a dataset that have higher consistency 832 levels. A similar situation may hold for the OOD dataset, OK-VQA, as shown in FIGS. 8B and 8E, and the adversarial dataset AdVQA, as shown in FIGS. 8C and 8F. In general, a model may be able to achieve lower risk on slices of a dataset on which consistency 832 of the model over rephrasings is higher. Thus, higher consistency 832 levels may identify questions on which a model can achieve lower risk across all datasets.

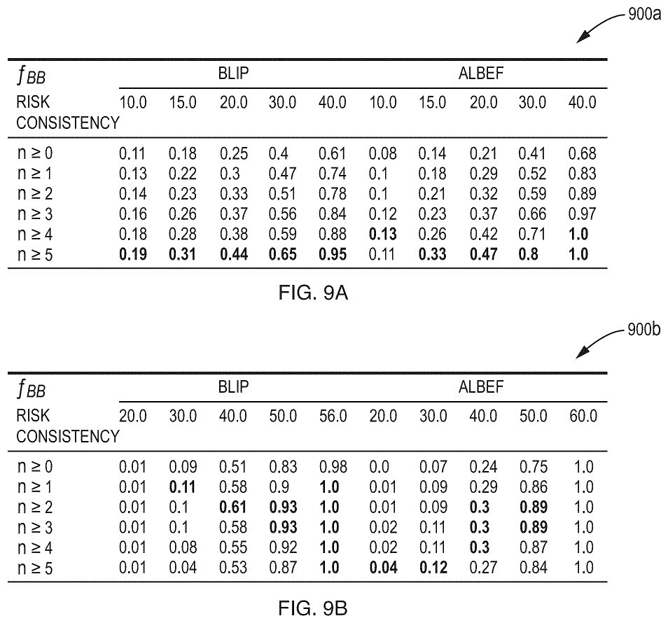

FIGS. 9A and 9B illustrate risk-coverage information in tabular form for OK-VQA and AdVQA, respectively, at specific risk levels. FIG. 9A is a table 900a of OK-VQA coverage at specified risk levels, stratified by consistency levels. n≥k indicates that the prediction of the model was consistent over at least k rephrasings of the question. FIG. 9B is a table 900b of AdVQA coverage at specified risk levels, stratified by consistency levels. n≥k indicates that the prediction of the model was consistent over at least k rephrasings of the question.

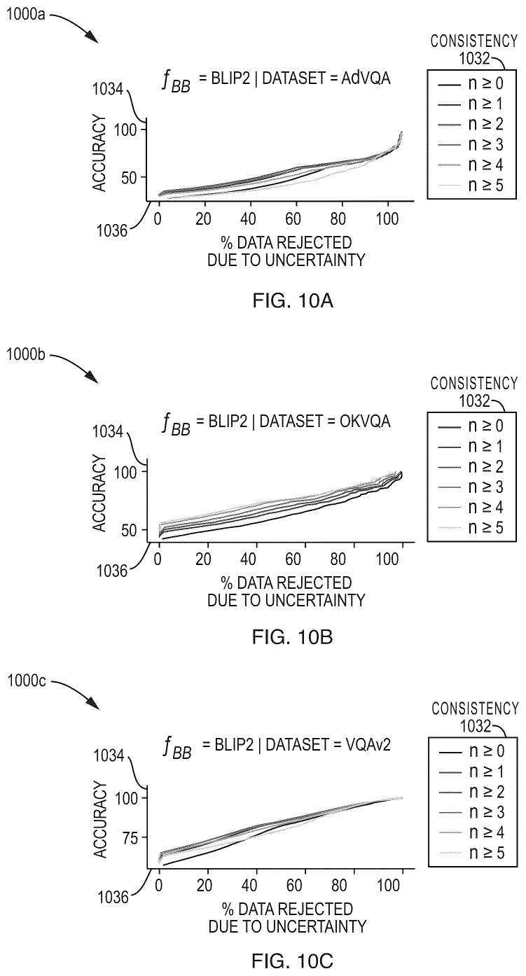

Finally, FIGS. 10A-10C illustrate that such an approach may work even when there is a large size difference between a black-box model and a question generator. FIGS. 10A-10C are plots 1000a, 1000b, and 1000c for datasets AdVQA, OK-VQA, and VQAv2, respectively, of risk-coverage curves when f_{VQG} (200 m parameters) is substantially smaller than f_{BB} (BLIP-2; 11b parameters) according to another example embodiment. Each of FIGS. 10A-10C plots percentage accuracy 1034 as a function of percentage of questions rejected due to uncertainty 1036. As shown in FIGS. 10A-10C, even in the scenarios depicted by plots 1000a-c, f_{VQC} can reliably identify high-risk questions based on consistency 1032. Further, in an example embodiment, high-risk questions may be cached or stored for later use.

### 5. Related Work

### 5.1. Selective Prediction

Deep models with a reject option have been studied in the context of unimodal classification and regression [8, 9, 37] for some time, and more recently for the open-ended task of question answering [15]. Deep models with a reject option in the context of VQA were first explored by Whitehead et al. [36]. They take an approach of training a selection function using features from a model and a held-out validation set to make a decision of whether to predict or abstain. The problem of eliciting truthful information from a language model [21] is closely related to selective prediction for VQA. In both settings, a model may avoid providing false information in response to a question.

### 5.2 Self-Consistency

Jha et al. [12] introduced an idea of using consistency over predictions of a model to quantify predictive uncertainty of the model. Their Attribution Based Confidence (ABC) metric is based on using guidance from feature attributions, specifically Integrated Gradients [33], to perturb samples in feature space, then using consistency over the perturbed samples to quantify predictive uncertainty. Shah et al. [30] show that VQA models are not robust to linguistic variations in a sentence by demonstrating inconsistency of answers of multiple VQA models over human-generated rephrasings of a sentence. Similarly, Selvaraju et al. [29] show that answers of VQA models to more complex reasoning questions are inconsistent with answers to simpler perceptual questions whose answers should entail an answer to the reasoning question. Embodiments leverage the insight that inconsistency on linguistic variations of a visual question may indicate a more superficial understanding of the question's content, and therefore may indicate a higher chance of being wrong when answering the question.

### 5.3. Robustness of VOA Models

VQA models have been shown to lack robustness, and are severely prone to overfitting on dataset-specific correlations rather than learning to answer questions. The VQA-CP (VQA under Changing Priors) [1] task showed that VQA models may often use linguistic priors to answer questions (e.g., the sky is usually blue), rather than looking at an image. Dancette et al. [7] showed that VQA models may often use simple rules based on co-occurrences of objects with noun phrases to answer questions. The existence of adversarial visual questions has also been demonstrated by [31], which used an iterative model-in-the-loop process to allow human annotators to attack state-of-the-art. While VQA models are approaching human-level performance on the VQAv2 benchmark [10], their performance on more complex VQA tasks such as OK-VQA lags far behind human performance.

### 6. Conclusion

The capital investment required to train large, powerful models on massive amounts of data means that there may be a strong commercial incentive to keep weights and features of a model private. Yet, there may be an equally powerful incentive to make a model accessible through an API while charging end-users a usage fee to recoup and profit from the capital investment required to train the model. While using such models in low-risk situations may be not problematic, using black-box models in situations where mistakes can have serious consequences may be dangerous. At the same time, the power of these black-box models may make using them very appealing.

Embodiments may provide a technique to judge reliability of an answer of a black-box VQA model by assessing consistency of the model's answer over rephrasings of an original question, which embodiments may generate dynamically using a VQG model. This may be analogous to a technique of consistency over neighborhood samples, which has been used in white-box settings for self-training as well as predictive uncertainty. For in-distribution, OOD, and adversarial settings, embodiments may demonstrate that consistency over rephrasings is correlated with model accuracy, and predictions of a model that are highly consistent over rephrasings may be more likely to be correct. Hence, embodiments may employ consistency over rephrasings to enable using a black-box VQA model reliably by identifying queries that the black-box model may not know an answer to.

### A. Detailed Risk-Coverage Data

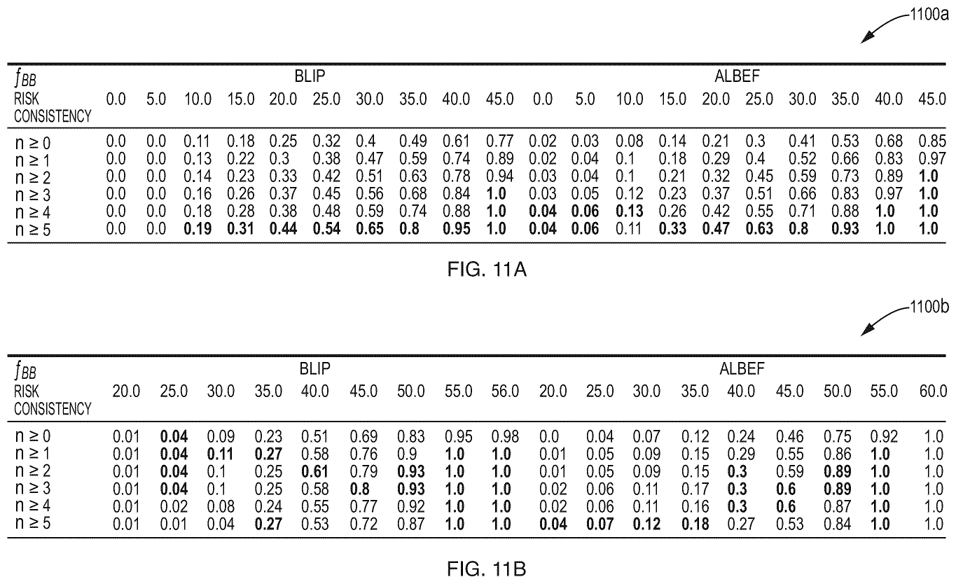

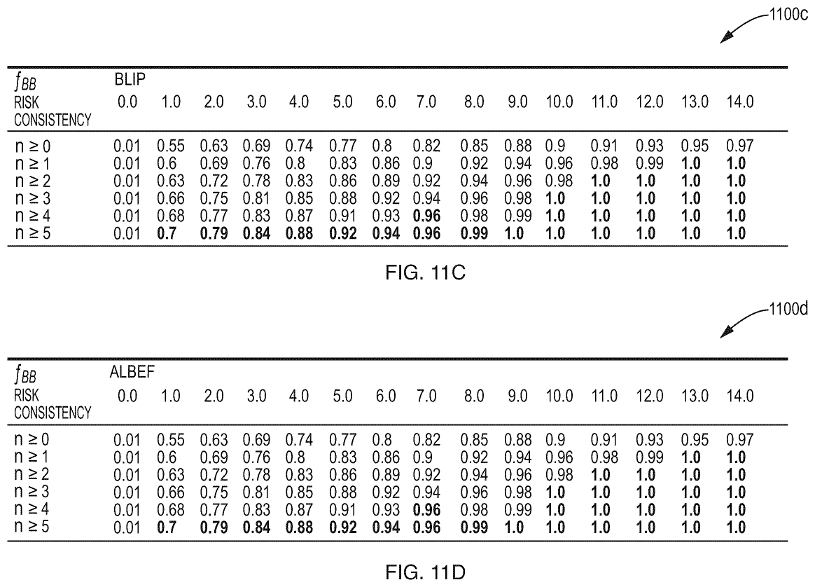

FIGS. 11A-11D illustrate more granular risk-coverage data in tabular form across three evaluated datasets and two black-box models. FIG. 11A is a table 1100a of more granular risk-coverage data for dataset OK-VQA across models BLIP and ALBEF. FIG. 11B is a table 1100b of more granular risk-coverage data for dataset AdVQA across models BLIP and ALBEF. FIG. 11C is a table 1100c of more granular risk-coverage data for dataset VQAv2 with BLIP as a black-box f_{BB}. FIG. 11D is a table 1100d of more granular risk-coverage data for dataset VQAv2 with ALBEF as a black-box f_{BB}.

### B. Inference Details

For both BLIP and ALBEF, embodiments may follow the original inference procedures. Both models have an encoder-decoder architecture and VQA may be treated as a text-to-text task. Embodiments may use, e.g., the rank-classification approach [4], to allow an autoregressive decoder of a VLM to predict an answer for a visual question. Concretely, let [symbol] ={a₁, a₂, a₃, . . . aₖ} be a list of length k for a dataset consisting of the most frequent GT answers. Such answer lists may be standardized and distributed by authors of the datasets themselves. Embodiments may use, e.g., standard answer lists for each dataset. Next, let v, q be a visual question pair and let f_{BB} be a VQA model. Recall that f_{BB} may be a language model defining a distribution p(a|q, v), and may thus be able to assign a score to each aᵢ∈ [symbol] . Embodiments may take the highest probability aₖ in exemplary Equation 2 below as a predicted answer for a question.

$${max}_{{a}_{k} ∈ 𝒜} {f}_{BB} ( v , q , {a}_{k} ) = {max}_{{a}_{k} ∈ 𝒜} p ( {a}_{k} \vert v , q ) \qquad ( 2 )$$

This may effectively ask the model to rank each possible answer candidate, turning an open-ended VQA task into a very large multiple-choice problem. Note that the highest probability aₖ may not necessarily be an answer that would be produced by f_{BB}˜p(a|v, q) in an unconstrained setting such as stochastic decoding. However, in some instances, embodiments may the rank classification approach.

VQA may thus be treated differently when using large autoregressive VLMs compared to non-autoregressive models. In traditional approaches, VQA may be treated as a classification task, and a standard approach used in older, non-autoregressive VLMs such as VILBERT (Vision-and-Language Bidirectional Encoder Representations from Transformers) [24] may be to train a Multi-Layered Perceptron (MLP) with a cross-entropy loss with each possible answer as a class.

### C. Rephrasings and Pseudo-Rephrasings

As shown in FIGS. 4A and 4B, some rephrasings are not literally rephrasings of an original question. It may be more correct to call the rephrasings pseudo-rephrasings, in the same way that generated labels are referred to as pseudo-labels in the semi-supervised learning literature [22]. However, the pseudo-rephrasings may be of sufficient quality that inconsistency over the pseudo-rephrasings may indicate potentially unreliable predictions from a f_{BB}.

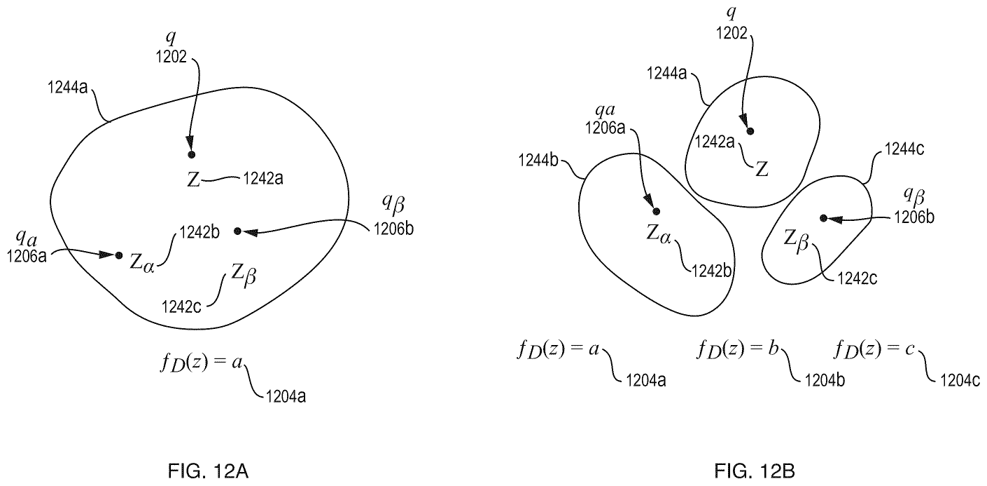

Why does this work? FIGS. 12A and 12B illustrate mapping rephrasings into parts of an embedding space according to an example embodiment. Decompose f_{BB} as f_{BB}=f_{D}(f_{E}(v, q)), where f_{E}(v, q)=z is the encoder that maps a visual question pair v, q to a dense representation z, and f_{D}(z)=a is the decoder that maps the dense representation z to an answer. For two rephrasings q_{α}, q_{β} of a question q, the model will be consistent over the rephrasings if all the rephrasings are embedded onto a subset of the embedding space that f_{D} assigns the same answer a. This is the situation depicted in FIG. 12A. As shown in FIG. 12A, question 1202 and two rephrasings 1206a and 1206b are mapped to dense representations 1242a, 1242b, and 1242c, respectively. In turn, all three dense representations 1242a-c belong to the same subset 1244a of an embedding space that maps to an answer 1204a.

Conversely, if q_{α} and q_{β} are embedded into parts of the embedding space that f_{D} assigns them different answers, the answers will not be consistent. As shown in FIG. 12B, if question 1202's dense representation 1242a continues to belong to subset 1244a, but rephrasing 1206a's dense representation 1242b and rephrasing 1206b's dense representation 1242c instead belong to different subsets 1244b and 1244c, respectively, then rephrasings 1206a and 1206b will be mapped to answers 1204b and 1204c, respectively, that are different from answer 1204a. Thus, whether a q_{α}, q_{β} are linguistically valid rephrasings does not matter so much as if q_{α}, q_{β} should technically have the same answer as the original question q. Of course, it is true that the answer to a linguistically valid rephrasing should be the same as the same as the answer to the question being rephrased. However, for any question, there are many other questions that have the same answer but are not rephrasings of the original question.

### D. Calibration

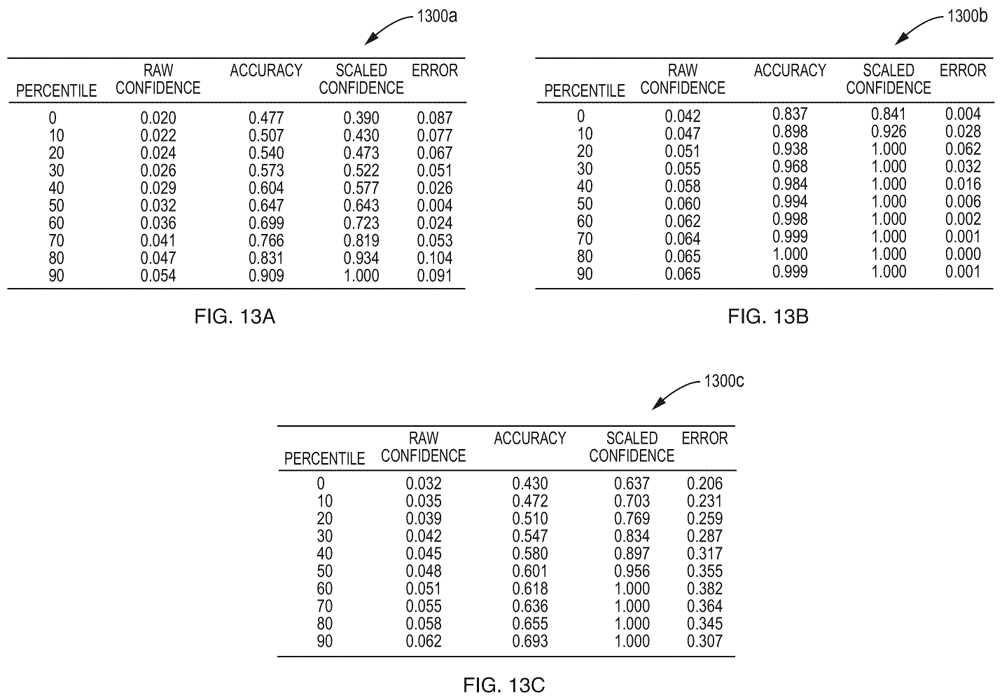

The confidence scores in FIGS. 3A-3C and 6A-6C, described hereinabove, may be raw scores from logits of a VQA model, such as BLIP. Recall that such models may be autoregressive models that approximate a probability distribution p(a|v, q), where a can take on an infinite number of values-a model may be able to assign a score to any natural language sentence. A raw distribution of confidence scores may be clearly truncated in the sense that all scores may appear to lie in an interval [0, 0.07]. Temperature scaling [27] may be applied to assess how well the confidence scores are calibrated. In temperature scaling, logits of a model may be multiplied by a parameter t. This may be rank-preserving, and may yield confidence scores that are more directly interpretable. Temperature scaling can be used to rescale model logits into an interval [0, 1] and analyze Adaptive Calibration Error [28], also referred to interchangeably as Adaptive Expected Calibration Error (ECE), of the model's predictions. A grid search may be performed for a t that minimizes Adaptive ECE directly on model predictions. FIGS. 13A-13C illustrate the results in tabular form. FIG. 13A is a table 1300a of data for calibration of BLIP on OK-VQA using a temperature of 19.9 for scaling. FIG. 13B is a table 1300b of data for calibration of BLIP on VQAv2 using a temperature of 19.3 for scaling. FIG. 13C is a table 1300c of data for calibration of BLIP on AdVQA using a temperature of 12.5 for scaling The Adaptive Calibration Error may be lowest on an in-distribution dataset (FIG. 13B), highest on an adversarial dataset (FIG. 13C), and second highest on an OOD dataset (FIG. 13A). Notably, a model may be systematically overconfident on adversarial samples, but not on OOD samples. This may suggest that calibration is not the only problem in selective prediction.

### E. Additional Rephrasing Examples

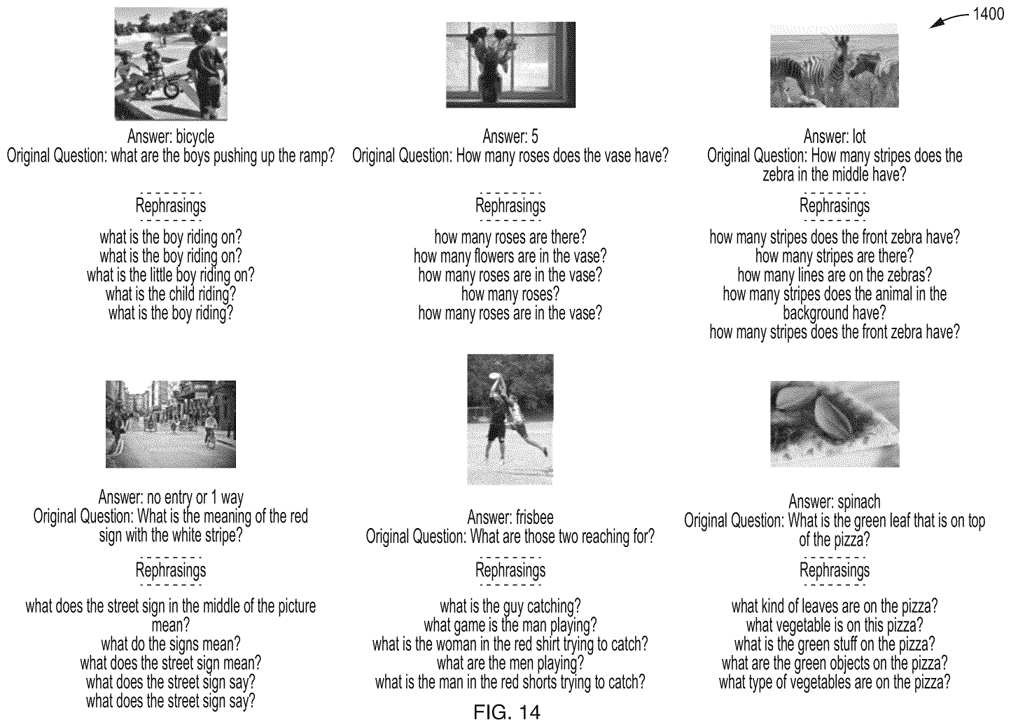

FIG. 14 is a chart 1400 illustrating additional generated rephrasings according to an example embodiment.

### F. Exemplary Method Embodiment

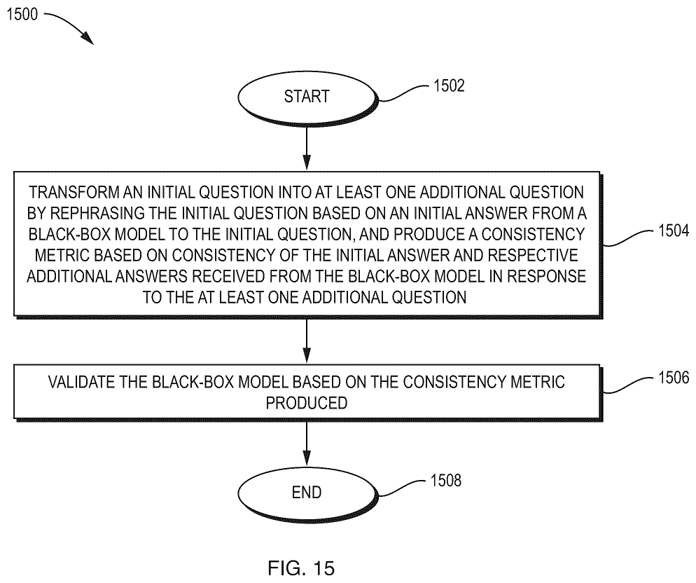

FIG. 15 is a flow diagram of an example embodiment of a computer-implemented method 1500 for validating a black-box model. The method 1500 begins 1502 and comprises transforming an initial question into at least one additional question by rephrasing the initial question based on an initial answer from the black-box model to the initial question, and producing a consistency metric based on consistency of the initial answer and respective additional answers received from the black-box model in response to the at least one additional question (1504). The method 1500 further comprises validating the black-box model based on the consistency metric produced (1506). The method 1500 thereafter ends 1508 in the example embodiment.

### G. Computer Support

FIG. 16 is a block diagram of an example embodiment of an internal structure of a computer 1600 in which various embodiments of the present disclosure may be implemented. The computer 1600 contains a system bus 1652, where a bus is a set of hardware lines used for data transfer among the components of a computer or digital processing system. The system bus 1652 is essentially a shared conduit that connects different elements of a computer system (e.g., processor, disk storage, memory, input/output (I/O) ports, network ports, etc.) that enables the transfer of information between the elements. Coupled to the system bus 1652 is an I/O device interface 1654 for connecting various input and output devices (e.g., keyboard, mouse, displays, printers, speakers, etc.) to the computer 1600. A network interface 1656 allows the computer 1600 to connect to various other devices attached to a network (e.g., global computer network, wide area network, local area network, etc.). Memory 1658 provides volatile or non-volatile storage for computer software instructions 1660 and data 1662 that may be used to implement embodiments (e.g., the method 1500, architecture 100a, architecture 100b, and computer-based system 110, etc.) of the present disclosure, where the volatile and non-volatile memories are examples of non-transitory media. Disk storage 1664 provides non-volatile storage for computer software instructions 1660 and data 1662 that may be used to implement embodiments (e.g., the method 1500, architecture 100a, architecture 100b, and computer-based system 110, etc.) of the present disclosure. A central processor unit 1666 is also coupled to the system bus 1652 and provides for the execution of computer instructions.

As used herein, the terms “model” and “module” may refer to any hardware, software, firmware, electronic control component, processing logic, and/or processor device, individually or in any combination, including without limitation: an application specific integrated circuit (ASIC), a field-programmable gate array (FPGA), an electronic circuit, a processor and memory that executes one or more software or firmware programs, and/or other suitable components that provide the described functionality.

Example embodiments disclosed herein may be configured using a computer program product; for example, controls may be programmed in software for implementing example embodiments. Further example embodiments may include a non-transitory computer-readable medium that contains instructions that may be executed by a processor, and, when loaded and executed, cause the processor to complete methods (e.g., the method 1500, etc.) described herein. It should be understood that elements of the block and flow diagrams may be implemented in software or hardware, such as via one or more arrangements of circuitry of FIG. 16, disclosed above, or equivalents thereof, firmware, a combination thereof, or other similar implementation determined in the future.

In addition, the elements of the block and flow diagrams described herein may be combined or divided in any manner in software, hardware, or firmware. If implemented in software, the software may be written in any language that can support the example embodiments disclosed herein. The software may be stored in any form of computer readable medium, such as random-access memory (RAM), read-only memory (ROM), compact disk read-only memory (CD-ROM), and so forth. In operation, a general purpose or application-specific processor or processing core loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments disclosed herein.

The teachings of all patents, published applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

### REFERENCES

[1] Aishwarya Agrawal, Dhruv Batra, Devi Parikh, and Anirudha Kembhavi. Don't just assume; look and answer: Overcoming priors for visual question answering. 2018 IEEE/CVF Conference on Computer Vision and Pattern Recognition, pages 4971-4980, 2017.
[2] Jakob Smedegaard Andersen, Tom Schoner, and Walid Maalej. Word-level uncertainty estimation for black-box text classifiers using RNNs. In Proceedings of the 28th International Conference on Computational Linguistics, pages 5541-5546, Barcelona, Spain (Online), 2020. International Committee on Computational Linguistics.
[3] Axel Brando, Damia Torres, Jose A. Rodriguez-Serrano, and Jordi Vitria. Building uncertainty models on top of black-box predictive apis. IEEE Access, 8:121344-121356, 2020.
[4] Tom B. Brown, Benjamin Mann, Nick Ryder, Melanie Subbiah, Jared Kaplan, Prafulla Dhariwal, Arvind Neelakantan, Pranav Shyam, Girish Sastry, Amanda Askell, Sandhini Agarwal, Ariel Herbert-Voss, Gretchen Krueger, T. J. Henighan, Rewon Child, Aditya Ramesh, Daniel M. Ziegler, Jeff Wu, Clemens Winter, Christopher Hesse, Mark Chen, Eric Sigler, Mateusz Litwin, Scott Gray, Benjamin Chess, Jack Clark, Christopher Berner, Sam McCandlish, Alec Radford, Ilya Sutskever, and Dario Amodei. Language models are few-shot learners. ArXiv, abs/2005.14165, 2020.
[5] N. Chomsky. The Logical Structure of Linguistic Theory. Springer, 1975.
[6] HyungWon Chung, Le Hou, S. Longpre, Barret Zoph, Yi Tay, William Fedus, Eric Li, XuezhiWang, Mostafa Dehghani, Siddhartha Brahma, AlbertWebson, Shixiang Shane Gu, Zhuyun Dai, Mirac Suzgun, Xinyun Chen, Aakanksha Chowdhery, Dasha Valter, Sharan Narang, Gaurav Mishra, Adams Wei Yu, Vincent Zhao, Yanping Huang, Andrew M. Dai, Hongkun Yu, Slav Petrov, Ed Huai hsin Chi, Jeff Dean, Jacob Devlin, Adam Roberts, Denny Zhou, Quoc V. Le, and Jason Wei. Scaling instruction-finetuned language models. ArXiv, abs/2210.11416, 2022.
[7] Corentin Dancette, Remi Cadene, Damien Teney, and Matthieu Cord. Beyond question-based biases: Assessing multimodal shortcut learning in visual question answering. 2021 IEEE/CVF International Conference on Computer Vision (ICCV), pages 1554-1563, 2021.
[8] Yonatan Geifman and Ran El-Yaniv. Selective classification for deep neural networks. In NIPS, 2017.
[9] Yonatan Geifman and Ran El-Yaniv. Selectivenet: A deep neural network with an integrated reject option. In International Conference on Machine Learning, 2019.
[10] Yash Goyal, Tejas Khot, Douglas Summers-Stay, Dhruv Batra, and Devi Parikh. Making the V in VQA matter: Elevating the role of image understanding in Visual Question Answering. In Conference on Computer Vision and Pattern Recognition (CVPR), 2017.
[11] Ari Holtzman, Jan Buys, Maxwell Forbes, and Yejin Choi. The curious case of neural text degeneration. ArXiv, abs/1904.09751, 2019.
[12] Susmit Jha, Sunny Raj, Steven Fernandes, Sumit K Jha, Somesh Jha, Brian Jalaian, Gunjan Verma, and Ananthram Swami. Attribution-Based Confidence Metric For Deep Neural Networks. In Advances in Neural Information Processing Systems. Curran Associates, Inc., 2019.
[13] Zhengbao Jiang, J. Araki, Haibo Ding, and Graham Neubig. How can we know when language models know? on the calibration of language models for question answering. Transactions of the Association for Computational Linguistics, 9:962-977, 2020.
[14] Saurav Kadavath, Tom Conerly, Amanda Askell, T. J. Henighan, Dawn Drain, Ethan Perez, Nicholas Schiefer, Zachary Dodds, Nova DasSarma, Eli Tran-Johnson, Scott Johnston, Sheer El-Showk, Andy Jones, Nelson Elhage, Tristan Hume, Anna Chen, Yuntao Bai, Sam Bowman, Stanislav Fort, Deep Ganguli, Danny Hernandez, Josh Jacobson, John Kernion, Shauna Kravec, Liane Lovitt, Kamal Ndousse, Catherine Olsson, Sam Ringer, Dario Amodei, Tom B. Brown, Jack Clark, Nicholas Joseph, Benjamin Mann, Sam McCandlish, Christopher Olah, and Jared Kaplan. Language models (mostly) know what they know. ArXiv, abs/2207.05221, 2022.
[15] Amita Kamath, Robin Jia, and Percy Liang. Selective question answering under domain shift. In Annual Meeting of the Association for Computational Linguistics, 2020.
[16] Ranjay Krishna, Yuke Zhu, Oliver Groth, Justin Johnson, Kenji Hata, Joshua Kravitz, Stephanie Chen, Yannis Kalantidis, Li-Jia Li, David A. Shamma, Michael S. Bernstein, and Li Fei-Fei. Visual genome: Connecting language and vision using crowdsourced dense image annotations. International Journal of Computer Vision, 123:32-73, 2016.
[17] Balaji Lakshminarayanan, Alexander Pritzel, and Charles Blundell. Simple and scalable predictive uncertainty estimation using deep ensembles. In NIPS, 2016.
[18] Junnan Li, Ramprasaath R. Selvaraju, Akhilesh Deepak Gotmare, Shafiq R. Joty, Caiming Xiong, and Steven C. H. Hoi. Align before fuse: Vision and language representation learning with momentum distillation. In Neural Information Processing Systems, 2021.
[19] Junnan Li, Dongxu Li, Caiming Xiong, and Steven C. H. Hoi. Blip: Bootstrapping language-image pre-training for unified vision-language understanding and generation. In International Conference on Machine Learning, 2022.
[20] Junnan Li, Dongxu Li, Silvio Savarese, and Steven Hoi. Blip-2: Bootstrapping language-image pre-training with frozen image encoders and large language models. ArXiv, abs/2301.12597, 2023.
[21] Stephanie C. Lin, Jacob Hilton, and Owain Evans. Truthfulqa: Measuring how models mimic human falsehoods. In Annual Meeting of the Association for Computational Linguistics, 2021.
[22] Hong Liu, Jianmin Wang, and Mingsheng Long. Cycle self-training for domain adaptation. In Neural Information Processing Systems, 2021.
[23] Ilya Loshchilov and Frank Hutter. Fixing weight decay regularization in adam. ArXiv, abs/1711.05101, 2017.
[24] Jiasen Lu, Dhruv Batra, Devi Parikh, and Stefan Lee. Vilbert: Pretraining task-agnostic visiolinguistic representations for vision-and-language tasks. In Neural Information Processing Systems, 2019.
[25] Kenneth Marino, Mohammad Rastegari, Ali Farhadi, and Roozbeh Mottaghi. Ok-vqa: A visual question answering benchmark requiring external knowledge. 2019 IEEE/CVF Conference on Computer Vision and Pattern Recognition (CVPR), pages 3190-3199, 2019.
[26] Hussein Mozannar and David A. Sontag. Consistent estimators for learning to defer to an expert. In International Conference on Machine Learning, 2020.
[27] Alexandru Niculescu-Mizil and Rich Caruana. Predicting good probabilities with supervised learning. In Proceedings of the 22nd International Conference on Machine Learning, page 625-632, New York, NY, USA, 2005. Association for Computing Machinery.
[28] Jeremy Nixon, Michael W. Dusenberry, Linchuan Zhang, Ghassen Jerfel, and Dustin Tran. Measuring calibration in deep learning. ArXiv, abs/1904.01685, 2019.
[29] Ramprasaath R. Selvaraju, Purva Tendulkar, Devi Parikh, Eric Horvitz, Marco Tulio Ribeiro, Besmira Nushi, and Ece Kamar. Squinting at vqa models: Introspecting vqa models with sub-questions. 2020 IEEE/CVF Conference on Computer Vision and Pattern Recognition (CVPR), pages 10000-10008, 2020.
[30] Meet Shah, Xinlei Chen, Marcus Rohrbach, and Devi Parikh. Cycle-consistency for robust visual question answering. In 2019 Conference on Computer Vision and Pattern Recognition (CVPR). IEEE.
[31] Sasha Sheng, Amanpreet Singh, Vedanuj Goswami, Jose Alberto Lopez Magana, Wojciech Galuba, Devi Parikh, and Douwe Kiela. Human-adversarial visual question answering. 2021.
[32] Tianxiang Sun, Yunfan Shao, Hong Qian, Xuanjing Huang, and Xipeng Qiu. Black-box tuning for language-model-as-a-service. ArXiv, abs/2201.03514, 2022.
[33] Mukund Sundararajan, Ankur Taly, and Qiqi Yan. Axiomatic attribution for deep networks. ArXiv, abs/1703.01365, 2017.
[34] Joost van Amersfoort, Lewis Smith, YeeWhye Teh, and Yarin Gal. Uncertainty estimation using a single deep deterministic neural network. 2020.
[35] Yulin Wang, Xuran Pan, Shiji Song, Hong Zhang, Cheng Wu, and Gao Huang. Implicit semantic data augmentation for deep networks. In Neural Information Processing Systems, 2019.
[36] Spencer Whitehead, Suzanne Petryk, Vedaad Shakib, Joseph E. Gonzalez, Trevor Darrell, Anna Rohrbach, and Marcus Rohrbach. Reliable visual question answering: Abstain rather than answer incorrectly. In European Conference on Computer Vision, 2022.
[37] Liu Ziyin, Zhikang T. Wang, Paul Pu Liang, Ruslan Salakhutdinov, Louis-Philippe Morency, and Masahito Ueda. Deep gamblers: Learning to abstain with portfolio theory. ArXiv, abs/1907.00208, 2019.

What is claimed is:

1. A computer-implemented method for validating a black-box model, the computer-implemented method comprising:
transforming an initial question into at least one additional question by rephrasing the initial question based on an initial answer from the black-box model to the initial question, and producing a consistency metric based on consistency of the initial answer and respective additional answers received from the black-box model in response to the at least one additional question; and
validating the black-box model based on the consistency metric produced.

2. The computer-implemented method of claim 1, wherein the black-box model is at least one of a multimodal model and a vision-language model (VLM).

3. The computer-implemented method of claim 1, wherein the validating includes identifying a subsequent answer as correct or incorrect, the subsequent answer received from the black-box model in response to a subsequent question from an end user, wherein the identifying includes determining a probability that the subsequent answer is a correct response to the subsequent question, and wherein the computer-implemented method further comprises:
alerting the end user that the subsequent answer is correct or incorrect based on the probability determined.

4. The computer-implemented method of claim 1, further comprising:
dynamically preempting display of a subsequent answer to an end user based on the consistency metric produced, the subsequent answer received from the black-box model in response to a subsequent question, the subsequent question received from the end user.

5. The computer-implemented method of claim 1, further comprising:
producing a risk metric for a subsequent question to the black-box model based on the consistency metric produced, the subsequent question received from an end user, the risk metric representing a probability that a subsequent answer received from the black-box model in response to the subsequent question is incorrect; and
preempting transmission of the subsequent question to the black-box model responsive to the risk metric produced exceeding a threshold value.

6. The computer-implemented method of claim 1, wherein the validating includes:
ranking the initial answer and the respective additional answers based on relative consistency of the initial answer and the respective additional answers.

7. The computer-implemented method of claim 1, wherein the validating includes:
determining a deviation between respective consistencies of the respective additional answers and respective confidence scores for the respective additional answers, the respective confidence scores output by the black-box model; and
responsive to the deviation determined exceeding a threshold value, alerting an end user to the deviation determined.

8. The computer-implemented method of claim 1, wherein the rephrasing includes:
probabilistically sampling a distribution of potential questions to generate a given additional question of the at least one additional question.

9. The computer-implemented method of claim 8, wherein the probabilistically sampling includes:
performing nucleus sampling;
determining a probability that the given additional question will cause the black-box model to produce the initial answer in response to the given additional question; and
generating the given additional question by implicitly perturbing a representation of the initial question in a feature space, the feature space associated with the black-box model.

10. A computer-based system for validating a black-box model, the computer-based system comprising:
a question generation model configured to transform an initial question into at least one additional question by rephrasing the initial question based on an initial answer from the black-box model to the initial question;
at least one processor; and
a memory with computer code instructions stored thereon, the at least one processor and the memory, with the computer code instructions, configured to cause the computer-based system to:
implement a validation module, the validation module configured to:
produce a consistency metric based on consistency of the initial answer and respective additional answers received from the black-box model in response to the at least one additional question; and
validate the black-box model based on the consistency metric produced.

11. The computer-based system of claim 10, wherein the black-box model is at least one of a multimodal model and a vision-language model (VLM).

12. The computer-based system of claim 10, wherein the validation module is further configured to identify a subsequent answer as correct or incorrect, the subsequent answer received from the black-box model in response to a subsequent question from an end user, wherein, to identify the subsequent answer as correct or incorrect, the validation module is further configured to determine a probability that the subsequent answer is a correct response to the subsequent question, and wherein the validation module is further configured to:
alert the end user that the subsequent answer is correct or incorrect based on the probability determined.

13. The computer-based system of claim 10, wherein the validation module is further configured to:
dynamically preempt display of a subsequent answer to an end user based on the consistency metric produced, the subsequent answer received from the black-box model in response to a subsequent question, the subsequent question received from the end user.

14. The computer-based system of claim 10, wherein the validation module is further configured to:
produce a risk metric for a subsequent question to the black-box model based on the consistency metric produced, the subsequent question received from an end user, the risk metric representing a probability that a subsequent answer received from the black-box model in response to the subsequent question is incorrect; and
preempt transmission of the subsequent question to the black-box model responsive to the risk metric produced exceeding a threshold value.

15. The computer-based system of claim 10, wherein the validation module is further configured to:
rank the initial answer and the respective additional answers based on relative consistency of the initial answer and the respective additional answers.

16. The computer-based system of claim 10, wherein the validation module is further configured to:
determine a deviation between respective consistencies of the respective additional answers and respective confidence scores for the respective additional answers, the respective confidence scores output by the black-box model; and
responsive to the deviation determined exceeding a threshold value, alert an end user to the deviation determined.

17. The computer-based system of claim 10, wherein the question generation model is further configured to:
probabilistically sample a distribution of potential questions to generate a given additional question of the at least one additional question.

18. The computer-based system of claim 17, wherein the question generation model is further configured to:
determine a probability that the given additional question will cause the black-box model to produce the initial answer in response to the given additional question.

19. The computer-based system of claim 17, wherein the question generation model is further configured to:
generate the given additional question by implicitly perturbing a representation of the initial question in a feature space, the feature space associated with the black-box model.

20. A non-transitory computer-readable medium having encoded thereon a sequence of instructions which, when loaded and executed by at least one processor, causes the at least one processor to:
transform an initial question into at least one additional question by rephrasing the initial question based on an initial answer from the black-box model to the initial question;
produce a consistency metric based on consistency of the initial answer and respective additional answers received from the black-box model in response to the at least one additional question; and
validate the black-box model based on the consistency metric produced.
